(19) United States
(12) Patent Application Publication
(10) Pub. No.: US 2024/0282557 A1
(43) Pub. Date: Aug. 22, 2024

(54) SUBSTRATE PROCESSING APPARATUS AND SUBSTRATE PROCESSING METHOD USING THE SAME

(71) Applicant: Samsung Electronics Co., Ltd., Suwon-si (KR)

(72) Inventors: JINUK PARK, Suwon-si (KR); EUIJIN PARK, Suwon-si (KR); DONGYUP CHOO, Suwon-si (KR)

(21) Appl. No.: 18/383,207

(22) Filed: Oct. 24, 2023

(30) Foreign Application Priority Data
Feb. 17, 2023 (KR) 10-2023-0021458
Apr. 12, 2023 (KR) 10-2023-0048390

(51) Int. Cl. H01J 37/32

(52) U.S. Cl. CPC H01J 37/32935; H01J 37/3244; H01J 37/32541; H01J 37/32715; H01J 2237/2007; H01J 2237/24564

(57) ABSTRACT

Disclosed is a substrate processing apparatus, which includes a power supply unit, a process chamber configured to receive power from the power supply unit, a cable unit connected between the power supply unit and the process chamber, and an impedance matching unit connected between the cable unit and the power supply unit and that matches an impedance of the power supply unit with an impedance of the process chamber and the cable unit, and the cable unit includes a cable that connects the power supply unit to the process chamber, an impedance measuring unit that measures an impedance of the entirety of the cable unit, and an impedance adjusting unit that adjusts the impedance of the entirety of the cable unit.

### CROSS-REFERENCE TO RELATED APPLICATIONS

This application claims priority under 35 U.S.C. § 119 to Korean Patent Application Nos. 10-2023-0021458 filed on Feb. 27, 2023 and 10-2023-0048390 filed on Apr. 12, 2023, respectively, in the Korean Intellectual Property Office, the disclosures of which are incorporated by reference herein in their entireties.

### BACKGROUND

Embodiments of the present disclosure described herein relate to a substrate processing apparatus and a substrate processing method using the same.

Alternating current (AC) power of various frequencies may be supplied to a substrate processing apparatus. Plasma may be generated and controlled by the AC power. In more detail, it is possible to control plasma concentration of a central portion of a substrate or a sheath shape of the plasma of an edge portion of the substrate using AC power. In this case, an impedance controller of the substrate processing apparatus may be used as a uniformity controlling circuit (UCP). The uniformity controlling circuit may be used to control the uniformity of the plasma. The uniformity controlling circuit may include capacitors and various other components.

### SUMMARY

Embodiments of the present disclosure relate to a substrate processing apparatus including a cable unit capable of adjusting impedance by itself and a substrate processing method using the same.

Embodiments of the present disclosure provide a substrate processing apparatus and a substrate processing method using the same that may adjust the impedance of a process chamber and an entirety of the cable unit using the cable unit connected between an impedance matching unit and the process chamber.

Embodiments of the present disclosure provide a substrate processing apparatus that may adjust the impedance of the entirety of the cable unit and a substrate processing method using the same.

Embodiments of the present disclosure provide a substrate processing apparatus that may filter a specific harmonic component of AC power and a substrate processing method using the same.

Embodiments of the present disclosure provide a substrate processing apparatus that may control plasma in a central portion of a substrate by matching the impedance of a power supply unit with the impedance of a process chamber and the cable unit, and a substrate processing method using the same.

The problem to be solved by the present disclosure may not be limited to the problems mentioned above, and other problems not mentioned will be clearly understood by those skilled in the art from the following description.

According to an embodiment of the present disclosure, a substrate processing apparatus includes a power supply unit, a process chamber configured to receive power from the power supply unit, a cable unit connected between the power supply unit and the process chamber, and an impedance matching unit connected between the cable unit and the power supply unit and that matches an impedance of the power supply unit with an impedance of the process chamber and the cable unit, and the cable unit includes a cable that connects the power supply unit to the process chamber, an impedance measuring unit that measures an impedance of the entirety of the cable unit, and an impedance adjusting unit that adjusts the impedance of the entirety of the cable unit.

According to an embodiment of the present disclosure, a substrate processing apparatus includes a power supply unit including a plurality of AC power sources, a process chamber receiving power from the power supply unit, and a cable unit disposed between the power supply unit and the process chamber, and the cable unit includes a cable that connects the power supply unit to the process chamber, an impedance measuring unit that measures an impedance of the entirety of the cable unit, and an impedance adjusting unit that adjusts the impedance of the entirety of the cable, and a frequency range of one of the plurality of AC power sources is 58 MHz to 62 MHz.

According to an embodiment of the present disclosure, a substrate processing method includes loading a substrate into a substrate processing apparatus, performing a process on the substrate in the substrate processing apparatus, unloading the substrate from the substrate processing apparatus, and adjusting an impedance of the substrate processing apparatus, and the substrate processing apparatus includes a process chamber, a power supply unit providing power to the process chamber, and a cable unit disposed between the power supply unit and the process chamber, and the cable unit includes a cable, an impedance measuring unit that measures an impedance of the entirety of the cable unit, and the substrate processing apparatus includes a process chamber, a power supply unit providing power to the process chamber, and a cable unit disposed between the power supply unit and the process chamber, and the cable unit includes a cable, an impedance measuring unit that measures an impedance of the entirety of the cable unit, and an impedance adjusting unit that adjusts the impedance of the entirety of the cable, and the adjusting of the impedance of the substrate processing apparatus includes isolating the cable from the process chamber, measuring the impedance of the entirety of the cable unit, and adjusting the impedance of the entirety of the cable unit.

Details of other embodiments are included in the detailed description and drawings.

### BRIEF DESCRIPTION OF THE FIGURES

A detailed description of each drawing is provided to facilitate a more thorough understanding of the drawings referenced in the detailed description of the present disclosure.

FIG. 1 is a cross-sectional view illustrating a substrate processing apparatus, according to example embodiments of the present disclosure.

FIG. 2 is an enlarged cross-sectional view of a portion of a process chamber of the substrate processing apparatus of FIG. 1, according to example embodiments of the present disclosure.

FIG. 3 is an enlarged cross-sectional view of a portion of a process chamber of the substrate processing apparatus of FIG. 1, according to example embodiments of the present disclosure.

FIG. 4 is a schematic diagram illustrating an impedance matching unit, according to example embodiments of the present disclosure.

FIG. 5 is a perspective view illustrating a cable unit, according to example embodiments of the present disclosure.

FIG. 6 is a front view illustrating a cable unit, according to example embodiments of the present disclosure.

FIG. 7 is a schematic diagram illustrating a configuration of a cable unit, according to example embodiments of the present disclosure.

FIG. 8 is a schematic diagram illustrating an impedance adjusting unit of a cable unit, according to example embodiments of the present disclosure.

FIG. 9 is a cross-sectional view illustrating a variable capacitor, according to example embodiments of the present disclosure.

FIG. 10 is a flowchart illustrating a substrate processing method, according to example embodiments of the present disclosure.

### DETAILED DESCRIPTION

Hereinafter, embodiments of the present disclosure will be described with reference to the accompanying drawings. In the present specification and drawings, the same reference characters may refer to the same components throughout.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim). Unless otherwise indicated, the use of ordinal numbers does not indicate any particular order or arrangement of an element.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. As used herein, items described as being “fluidly connected” are configured such that a liquid or gas can flow, or be passed, from one item to the other.

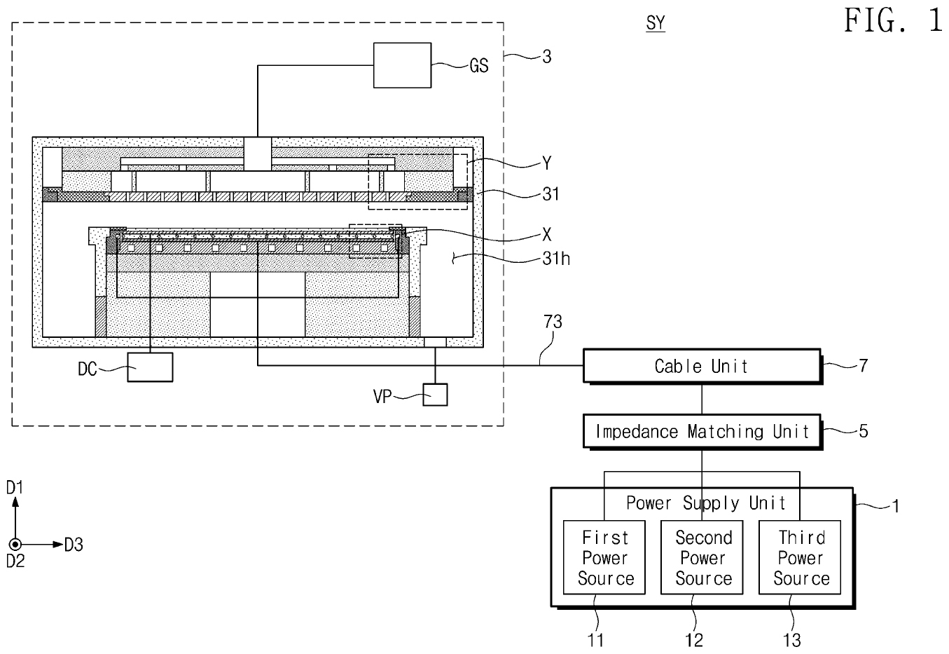

Hereinafter, D1 as shown in FIGS. 1, 2, and 3 may be referred to as a first direction, D2 as shown in FIGS. 1, 2, and 3 which intersects the first direction D1 may be referred to as a second direction, and D3 which intersects each of the first and second directions D1 and D2 may be referred to as a third direction. The first direction D1 may be referred to as an upward direction, and a direction opposite to the first direction D1 may be referred to as a downward direction. In addition, each of the second direction D2 and the third direction D3 may be referred to as a horizontal direction.

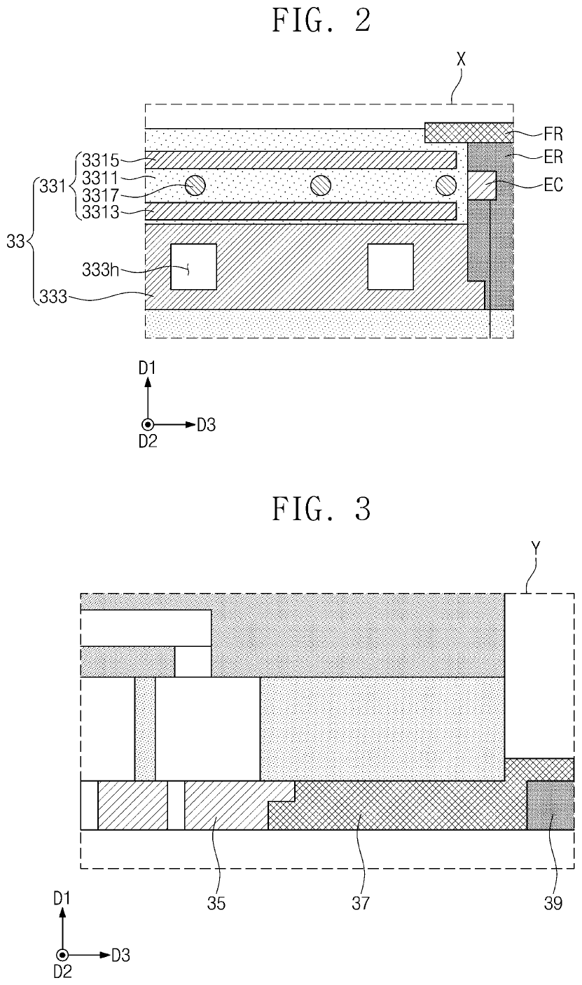

FIG. 1 is a cross-sectional view illustrating a substrate processing apparatus SY, according to example embodiments of the present disclosure, FIG. 2 is an enlarged cross-sectional view of a portion of a process chamber 3, according to example embodiments of the present disclosure, and FIG. 3 is an enlarged cross-sectional view of a portion of the process chamber 3, according to example embodiments of the present disclosure.

Referring to FIG. 1, the substrate processing apparatus SY may include a power supply unit 1, the process chamber 3 receiving power from the power supply unit 1, a cable unit 7 disposed between the power supply unit 1 and the process chamber 3, and an impedance matching unit 5 disposed between the cable unit 7 and the power supply unit 1 and that matches an impedance of the power supply unit 1 with an impedance of the process chamber 3 and the cable unit 7.

The power supply unit 1 may provide AC power. The AC power may be provided to the process chamber 3. The power supply unit 1 may include at least one power source. FIG. 1 illustrates that the power supply unit 1 is configured to include three power sources 11, 12 and 13, but the number of power sources included in the power supply unit 1 may be one or two, or four or more. Hereinafter, the configuration of the power supply unit 1 with three power sources 11, 12 and 13 will be mainly described.

A plurality of power sources may produce AC power of different frequencies (e.g., each power source may produce AC power at a different frequency). For example, a first power source 11 may produce AC power having a frequency range of 390 kHz to 410 kHz. More specifically, the first power source 11 may produce AC power having a frequency of 400 kHz. A second power source 12 may produce AC power having a frequency range of 8 MHz to 10 MHz. More specifically, the second power source 12 may produce AC power having a frequency of 9 MHz. A third power source 13 may produce AC power having a frequency range of 58 MHz to 62 MHz. More specifically, the third power source 13 may produce AC power having a frequency of 60 MHz. The AC power generated by at least one of the plurality of power sources 11, 12, and 13 may be provided to the process chamber 3. In detail, the process chamber 3 may receive AC power generated by at least one or more power sources 11, 12, and 13 1of the power supply unit 1.

Referring to FIGS. 1, 2, and 3, a semiconductor manufacturing process, such as an etching process and/or a deposition process may be performed on a substrate in the process chamber 3 The term ‘substrate’ used herein may mean a silicon (Si) wafer, but is not limited thereto. The semiconductor manufacturing process may be performed using plasma in the process chamber 3. To this end, the process chamber 3 may generate plasma in various ways. For example, the process chamber 3 may include a capacitively coupled plasma (CCP) plasma generator and/or an inductively coupled plasma (ICP) plasma generator. However, hereinafter, for convenience of description, it will be illustrated and described based on the inclusion of a CCP plasma generator. The process chamber 3 may include a chamber body 31, a stage 33, a shower head 35, an outer ring 37, a heating liner ring 39, a direct current (DC) power generator DC, a vacuum pump VP, and a gas supply device GS.

The chamber body 31 may provide a process space 31h. A process on the substrate may be performed in the process space 31h. The process space 31h may be separated from an external space (e.g., space external to the chamber body). While a process on the substrate is in progress, the process space 31h may be in a vacuum state. The chamber body 31 may have a cylindrical shape, but is not limited thereto.

The DC power generator DC may apply DC power to the stage 33. The substrate may be fixed at a predetermined position on the stage 33 by the DC power applied by the DC power generator DC (e.g., electrostatic forces may fix the substrate to the stage).

The vacuum pump VP may be fluidly connected to the process space 31h. As used herein, items described as being “fluidly connected” are configured such that a liquid or gas can flow, or be passed, from one item to the other. A vacuum pressure may be applied to the process space 31h by the vacuum pump VP while the process on the substrate is in progress.

The gas supply device GS is fluidly connected to the process space 31h and may supply gas to the process space 31h. To this end, the gas supply device GS may include a gas tank, a compressor, a valve, etc. Part of the gas supplied into the process space 31h by the gas supply device GS may become plasma through application of the AC power.

Referring to FIG. 2, an edge ring ER, an edge electrode EC, and a focus ring FR may be further provided. The edge ring ER may surround the stage 33. The edge ring ER may surround the stage 33 in a horizontal plane. The focus ring FR may be located on the edge ring ER (e.g., may overlap the edge ring ER in a vertical direction). The edge ring ER may support the focus ring FR. Plasma on the edge portion of the substrate may be precisely controlled by the focus ring FR.

The edge electrode EC may be located inside the edge ring ER. The edge electrode EC may surround a plasma electrode 3313 to control plasma in the edge area of the substrate. The edge electrode EC may surround the plasma electrode 3313 in a horizontal plane. The edge electrode EC may have a ring shape. The edge electrode EC may have a ring shape in a horizontal plane. The edge electrode EC may receive AC power from the power supply unit 1. The edge electrode EC may be electrically connected to the plasma electrode 3313. As used herein, components described as being “electrically connected” are configured such that an electrical signal can be transferred from one component to the other (although such electrical signal may be attenuated in strength as it is transferred and may be selectively transferred).

The stage 33 may include a chuck 331 and a cooling plate 333. A substrate may be placed on the chuck 331. The chuck 331 may fix the substrate at a predetermined position. To this end, the chuck 331 may include a chuck body 3311, the plasma electrode 3313, a chuck electrode 3315, and a heater 3317.

The chuck body 3311 may have a cylindrical shape. The chuck body 3311 may be formed of and/or include ceramic or the like, but is not limited thereto. The substrate may be disposed on an upper surface of the chuck body 3311. The edge ring ER may surround the chuck body 3311. The edge ring ER may surround the chuck body 3311 in a horizontal plane.

The plasma electrode 3313 may be located in the chuck body 3311. The plasma electrode 3313 may be formed of and/or include aluminum (Al) or the like. The plasma electrode 3313 may have a disk shape, but is not limited thereto. The AC power may be applied to the plasma electrode 3313. More specifically, the power supply unit 1 may be electrically connected to the plasma electrode 3313 and apply the AC power to the plasma electrode 3313. The plasma electrode 3313 may be electrically connected to the edge electrode EC. Plasma in the process space 31h (refer to FIG. 1) may be controlled by the AC power applied to the plasma electrode 3313.

The chuck electrode 3315 may be located within the chuck body 3311. The chuck electrode 3315 may be located above the plasma electrode 3313. DC power may be applied to the chuck electrode 3315. In more detail, the DC power generator DC may apply the DC power to the chuck electrode 3315. The substrate on the chuck body 3311 may be fixed in a predetermined position by the DC power applied to the chuck electrode 3315. The chuck electrode 3315 may be formed of and/or include aluminum (Al), but is not limited thereto.

The heater 3317 may be located within the chuck body 3311. The heater 3317 may be located between the chuck electrode 3315 and the plasma electrode 3313. The heater 3317 may include a hot wire. For example, the heater 3317 may include concentric heating wires. The heater 3317 may emit heat to the surroundings. Accordingly, the temperature of the chuck body 3311 or the like may rise from heat emitted from the heater 3317.

The cooling plate 333 may be located below the chuck 331. The cooling plate 333 may provide cooling holes 333h (e.g., passages). Cooling water may flow through the cooling holes 333h. The cooling water in the cooling holes 333h may absorb heat from the cooling plate 333.

Referring to FIG. 3, the shower head 35 may be located within the process chamber 3. In detail, the shower head 35 may be located within the chamber body 31. The shower head 35 may be disposed spaced apart and upward from the stage 33. The shower head 35 supplies gas to the process chamber 31. The gas may be supplied from the gas supply device GS and may be uniformly sprayed into the process space 31h through the shower head 35.

The outer ring 37 may surround the shower head 35. In detail, in a plan view, the outer ring 37 may surround the shower head 35 from the outside (e.g., a periphery) of the shower head 35. The outer ring 37 may contact the shower head 35.

The heating liner ring 39 may surround the outer ring 37. In detail, in a plan view, the heating liner ring 39 may surround the outer ring 37 from the outside (e.g., periphery) of the outer ring 37. The heating liner ring 39 may support the outer ring 37. The heating liner ring 39 may be formed of and/or include aluminum (Al) and yttrium oxide (Y₂O₃). More specifically, the heating liner ring 39 be formed of aluminum (Al) with an yttrium oxide (Y₂O₃) coating.

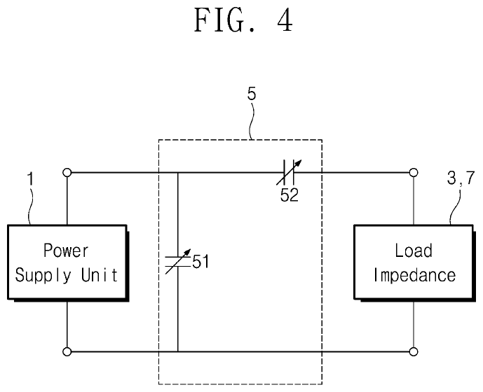

FIG. 4 is a schematic diagram illustrating an impedance matching unit 5 t, according to example embodiments of the present disclosure.

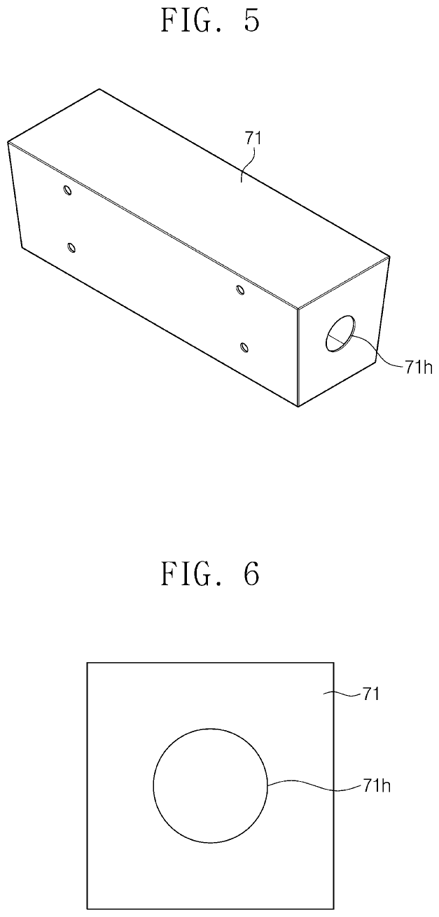

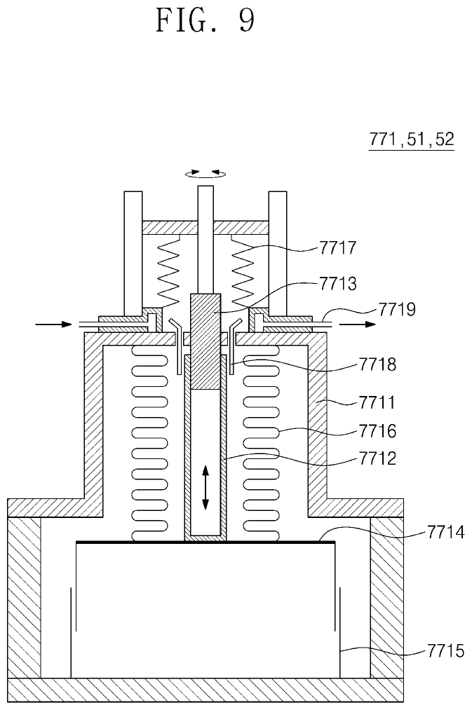

Referring to FIG. 4, the impedance matching unit 5 may be provided. The impedance matching unit 5 may be an edge block impedance controller (EBIC). The impedance matching unit 5 may be located between the power supply unit 1 and the process chamber 3. The impedance matching unit 5 may provide an electrical connection between the power supply unit 1 and the process chamber 3. The impedance matching unit 5 may match the impedance of the power supply unit 1 with the impedance of the process chamber 3 and the cable unit 7. Hereinafter, the impedance of the process chamber 3 and the cable unit 7 may be referred to as a load impedance. The cable unit 7 (refer to FIGS. 5 to 8) will be described later. The impedance matching unit 5 may include a plurality of variable capacitors 51 and 52. At least one of the plurality of variable capacitors 51 and 52 may include a vacuum variable capacitor (VVC). The variable capacitors 51 and 52 (refer to FIG. 9) will be described later.

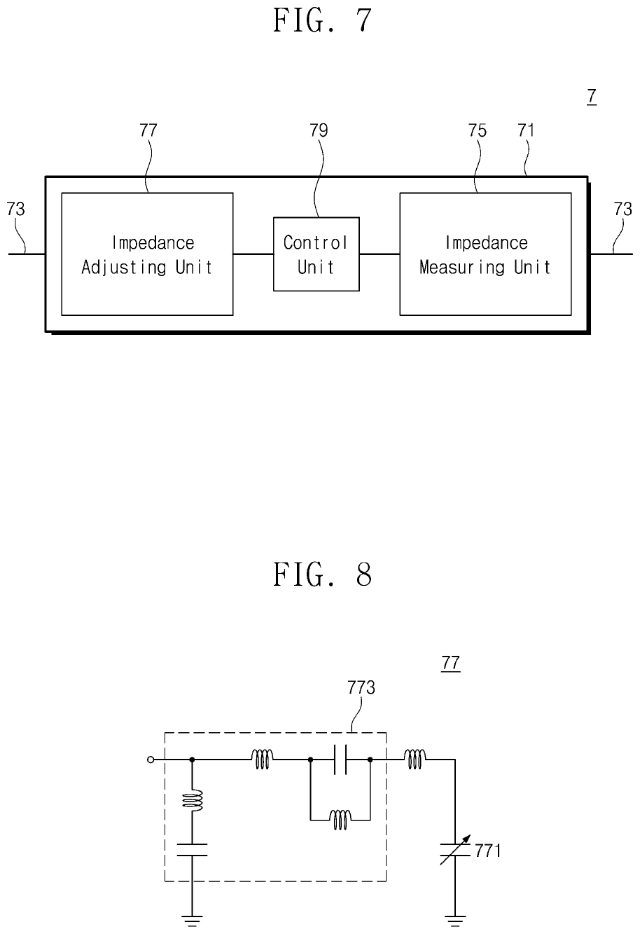

When the load impedance and the impedance of the power supply unit 1 do not match, an unintended reflected wave may occur. The reflected wave may affect the plasma in the process chamber 3. In detail, the plasma concentration at the center of the substrate or at the edge of the substrate may be changed by the reflected wave caused when the load impedance and the impedance of the power supply unit 1 do not match. Generation of the reflected wave may be prevented by adjusting the variable capacitors 51 and 52 of the impedance matching unit 5 to match the impedance of the power supply 1 to the load. The AC power having a frequency from 390 kHz to 410 kHz may be adjusted by adjusting the variable capacitors 51 and 52 of the impedance matching unit 5. More specifically, by controlling the variable capacitors 51 and 52 of the impedance matching unit 5 to adjust the AC power having a frequency of 400 kHz, it is possible to control the density of the plasma on the plasma electrode 3313 and the edge electrode EC, and/or the shape of the sheath, etc. When the impedance matching unit 5 adjusts AC power having a frequency of 400 kHz, the AC power with a frequency of 60 MHz may also change. Harmonics may be generated by a resonance phenomenon within the process chamber 3 for AC power having a frequency of 60 MHz. Harmonics may have frequencies that are integer multiples of a fundamental frequency. Harmonics having a frequency of 180 MHz (e.g., three times the fundamental 60 MHz AC power) may flow out of the process chamber 3 through a cable 73 (refer to FIG. 7) connected to the edge electrode EC.

FIG. 5 is a perspective view illustrating a cable unit 7, according to example embodiments of the present disclosure, FIG. 6 is a front view illustrating the cable unit 7, according to example embodiments of the present disclosure, FIG. 7 is a schematic diagram illustrating a configuration of the cable unit 7, according to example embodiments of the present disclosure, and FIG. 8 is a schematic diagram illustrating an impedance adjusting unit 77 of the cable unit 7, according to example embodiments of the present disclosure.

Referring to FIGS. 5, 6 and 7, the cable unit 7 may include a shielding box 71, a cable 73, an impedance measuring unit 75, an impedance adjusting unit 77, and a control unit 79.

Referring to FIGS. 5 and 6, the shielding box 71 may be formed of and/or include metal. The shielding box 71 may have a rectangular parallelepiped shape. One surface of the shield box 71 and a surface opposite to the one surface may provide a cable hole 71h through which the cable 73 may pass. The cable hole 71h may have a size that allows the cable 73 to pass therethrough. The cable hole 71h may have a circular shape, but is not limited thereto.

Referring to FIG. 7, the cable 73 may be connected to the impedance measuring unit 75, the impedance adjusting unit 77, and the control unit 79 inside the shielding box 71 through the cable hole 71h of the shielding box 71. The control unit 79 may be connected to the impedance measuring unit 75 and the impedance adjusting unit 77. The impedance measuring unit 75 may measure the impedance of the entire cable unit 7 (e.g., the entirety of the cable unit 7 including the impedance measuring unit 75, the impedance adjusting unit 77, and the cable 73). The control unit 79 may receive the impedance value of the entire cable unit 7 from the impedance measuring unit 75. The control unit 79 may control the impedance adjusting unit 77 to adjust the impedance of the entire cable unit 7. The control unit 79 may control the impedance adjusting unit 77 to adjust the impedance of the entire cable unit 7 to a set value.

The impedance measuring unit 75 may include a vector network analyzer (VNA). The impedance measuring unit 75 may transmit a signal to the entire cable unit 7 as part of measuring the impedance of the entire cable unit 7. The impedance measuring unit 75 may measure the impedance of the entire cable unit 7 using the signal transmitted to the entire cable unit 7 by comparing a signal reflected from the entire cable unit 7 with a signal passing through the entire cable unit 7. However, the impedance measuring method of the impedance measuring unit 75 is not limited thereto. The impedance measuring unit 75 may transmit impedance information of the entire cable unit 7 to the control unit 79. The impedance measuring unit 75 may transmit impedance information of the entire cable unit 7 to the impedance adjusting unit 77.

Referring to FIG. 8, the impedance adjusting unit 77 may adjust the impedance of the entire cable unit 7. The impedance adjusting unit 77 may include a filter 773 configured to cut off the power (e.g., reduce the power) at a specific frequency. More specifically, the filter 773 may reduce AC power having a frequency range of 175 MHz to 185 MHz. The filter 773 may further facilitate plasma control in the process chamber 3 by blocking AC power (e.g., the harmonics generated in the process chamber 3) flowing out of the process chamber 3. The filter 773 may include a capacitor and an inductor. The filter 773 is not limited to the configuration and structure of FIG. 8. The impedance adjusting unit 77 may include a variable capacitor 771 capable of adjusting the impedance of the entire cable unit 7. The variable capacitor 771 may include the VVC. The impedance adjusting unit 77 may automatically adjust the total impedance value of the cable unit 7 based on the total impedance value of the cable unit 7 measured by the impedance measuring unit 75.

The cable unit 7 may further include a data display unit (not illustrated) configured to display the impedance of the entire cable unit 7 as measured by the impedance measuring unit 75. The data display unit may include an LCD monitor, a seven segment display, etc.

FIG. 9 is a cross-sectional view illustrating the variable capacitors 771, 51, and 52, according to example embodiments of the present disclosure.

The variable capacitors 771, 51 and 52 may change capacitance. In more detail, the variable capacitors 771, 51 and 52 may change the capacitance by changing the distance between two electrodes. The variable capacitors 771, 51 and 52 may include the VVC.

Referring to FIG. 9, the variable capacitors 771, 51, and 52 may include a vacuum chamber 7711, a main bellows 7716, a moving electrode 7714, a fixed electrode 7715, a shaft 7712, and a rubber bellows 7717, a rotary driver 7713, a heat pipe 7718, and a cooling pipe 7719. The variable capacitors 771, 51, and 52 of FIG. 9 may be the variable capacitor 771 included in the impedance adjusting device 77 and may actually be the same as the variable capacitors 51 and 52 included in the impedance matching unit 5 in terms of structure.

The vacuum chamber 7711 may form bodies of the variable capacitors 771, 51, and 52. A vertical direction in FIG. 9 may be referred to as an axial direction of the vacuum chamber 7711. The fixed electrode 7715 and the moving electrode 7714 may be located under the vacuum chamber 7711. The fixed electrode 7715 and the moving electrode 7714 may be formed of and/or include a metal material. The fixed electrode 7715 may be coupled to the lower surface of the vacuum chamber 7711.

The shaft 7712 and the rotary driver 7713 may be elongated in the axial direction of the vacuum chamber 7711. The shaft 7712 may be rotated by an electric motor and mechanical drive mechanisms. The shaft 7712 may engage an upper surface of the moving electrode 7714. The shaft 7712 may move up and down in the axial direction. Movement of the shaft 7712 may move the moving electrode 7714 in the axial direction. The shaft 7712 may move in the axial direction by rotation of the rotary driver 7713. In other words, the shaft 7712 may be moved up and down by rotating the rotary driver 7713.

The moving electrode 7714 may be coupled to the underside of the shaft 7712. An overlapping area with the fixed electrode 7715 may be changed by the vertical movement of the moving electrode 7714. Capacitances of the variable capacitors 771, 51, and 52 may change as the overlap area between the moving electrode 7714 and the fixed electrode 7715 changes.

The main bellows 7716 may be coupled to an upper surface of the moving electrode 7714 and an inner surface facing the moving electrode 7714 in the vacuum chamber 7711. The main bellows 7716 may transfer current to the moving electrode 7714. The main bellows 7716 may cause the moving electrode 7714 to move down as the shaft 7712 moves down. The main bellows 7716 may provide a spring force that causes the moving electrode 7714 to move upward as the shaft 7712 moves upward. The interior of the main bellows 7716 may be filled with a heat transfer liquid. The heat transfer liquid may include an oil.

The internal volume of the rubber bellows 7717 may change when the rotary driver 7713 rotates. The rubber bellows 7717 may be formed of and/or include rubber. As the shaft 7712 moves up, the heat transfer liquid in the main bellows 7716 may move into the rubber bellows 7717.

The heat pipe 7718 may transfer heat from main bellows 7716 to the cooling pipe 7719. Cooling water may flow through the cooling pipe 7719. Water may flow through the cooling pipe 7719. Heat may travel from the heat transfer liquid in the main bellows 7716 through the heat pipe 7718 to the cooling pipe 7719. Fatigue of the variable capacitors 771, 51 and 52 and devices including the variable capacitors 771, 51 and 52 may be reduced by cooling the heat transfer liquid.

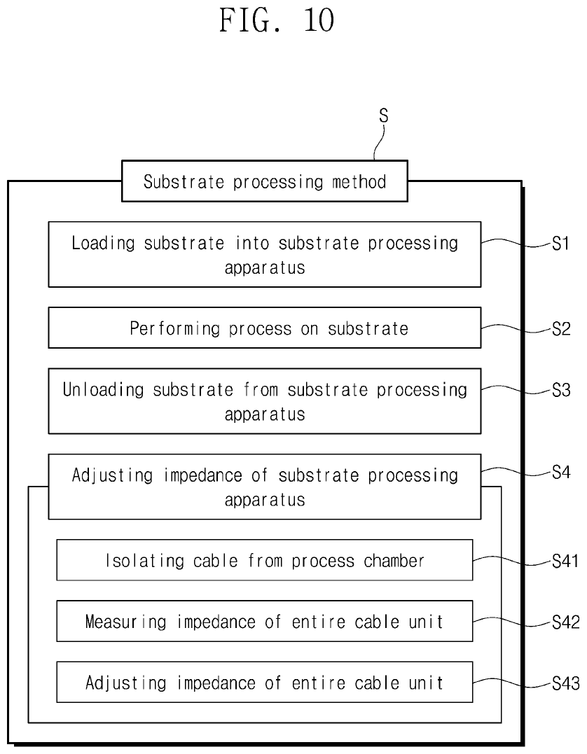

FIG. 10 is a flowchart illustrating a substrate processing method ‘S’, according to example embodiments of the present disclosure.

Referring to FIG. 10, a substrate processing method ‘S’ may include loading a substrate into the substrate processing apparatus SY (S1), performing a process on the substrate (S2), unloading the substrate from the substrate processing apparatus SY (S3), and adjusting the impedance of the substrate processing apparatus SY (S4) in preparation for performing a process on another substrate. The adjusting of the impedance of the substrate processing apparatus SY (S4) may include isolating the cable 73 from the process chamber 3 (S41), measuring the impedance of the entire cable unit 7 (S42), and adjusting the impedance of the entire cable unit 7 (S43).

Referring to FIGS. 1 and 10, loading of the substrate into the substrate processing apparatus SY (S1) may include placing the substrate on the stage 33. More specifically, the substrate may be located (placed) on the upper surface of the chuck body 3311. The substrate may be fixed on the chuck body 3311 by the DC power applied to the chuck electrode 3315.

The performing of the process on the substrate (S2) may include performing various processes related to semiconductor device manufacturing. More specifically, the various processes may include performing one of etching and deposition processes.

The unloading of the substrate from the substrate processing apparatus SY (S3) may include separating the substrate from the stage 33.

The isolating of the cable 73 from the process chamber 3 (S41) may include separating the cable 73 from the process chamber 3. The cable 73 may be separated from the process chamber 3 such that current does not flow (e.g., AC power is not transmitted to the process chamber 3 from the cable 73). More specifically, one end of the cable 73 may be exposed to the air, and the other end of the cable 73 may be connected to the impedance matching unit 5.

Referring to FIGS. 10 and 7, the measuring of the impedance of the entire cable unit 7 (S42) may include measuring the impedance of the entire cable unit 7 by the impedance measuring unit 75. The impedance measuring unit 75 may measure the impedance of the entire cable unit 7 using the VNA.

The adjusting of the impedance of the entire cable unit 7 (S43) may be performed by adjusting the variable capacitor 771 in the impedance adjusting unit 77. More specifically, the impedance of the entire cable unit 7 may be adjusted by adjusting the VVC.

A required value can be set for the entire cable unit 7 using the control unit 79. For example, an operator can set a value using the control unit 79. The control unit 79 may control the impedance adjusting unit 77 to set the impedance of the entire cable unit 7 to the set value. For example, the control unit 79 may receive the measured impedance value of the entire cable unit 7 from the impedance measuring unit 75 and adjust the variable capacitor 771 of the impedance adjusting unit 77 until the measured impedance value of the entire cable unit 7 matches the set value.

Although not illustrated, the control unit 79 can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the control unit 79 (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. The input/output devices may include controllers that can output and/or receive control signals for interacting with other units such as the impedance measuring unit 75 and the impedance adjusting unit 77. In addition, the control unit 79 can include antennas, network interfaces that provide wireless and/or wire line digital and/or analog interface to one or more networks over one or more network connections (not shown), and a bus that allows communication among the various disclosed components of the control unit 79.

According to embodiments of the present disclosure, the impedance of the entire cable unit may be adjusted based on the impedance value of the entire cable unit measured by the impedance measuring unit. When the impedance measuring unit measures the impedance value of the entire cable unit, the impedance control unit may adjust the variable capacitor to adjust the impedance value of the entire cable unit.

According to embodiments of the present disclosure, harmonics caused by AC power of the power supply unit may be filtered through a filter of the impedance adjusting unit. This allows the plasma in the process chamber to be more easily controlled.

According to embodiments of the present disclosure, plasma of the center and edge portion of the substrate may be controlled by matching the impedance of the power supply unit with the impedance of the process chamber and the cable unit using the impedance matching unit.

According to embodiments of the present disclosure, a process variable factor may be secured. In more detail, the plasma in the process chamber may be controlled by adjusting the impedance of the entire cable unit in the impedance adjusting unit. The shape or density of plasma on the center or edge of the substrate may be controlled by adjusting the variable capacitor of the impedance adjusting unit.

According to embodiments of the present disclosure, safety accidents may be prevented. More specifically, it is possible to adjust the impedance of the entire cable unit without replacing the cable. Therefore, accidents that may occur during cable replacement work may be prevented.

According to embodiments of the present disclosure, work time may be saved by reducing the frequency of changing cables. Since the capacitance of the total cable unit 7 may be automatically adjusted by the impedance adjusting unit, the time required to stop the process chamber and adjust the load impedance may be reduced.

According to embodiments of the present disclosure, the substrate processing apparatus and the substrate processing method using the same may adjust the impedance of the process chamber and the entire cable unit using the variable capacitor of the cable unit.

According to embodiments of the present disclosure, the substrate processing apparatus and the substrate processing method using the same may automatically adjust the impedance of the entire cable unit based on the impedance of the entire cable unit measured by the impedance measuring unit.

According to embodiments of the present disclosure, the substrate processing apparatus and the substrate processing method using the same may filter specific harmonic components caused by AC power.

According to embodiments of the present disclosure, the substrate processing apparatus and the substrate processing method using the same may control plasma in the center and edge portions of the substrate by matching the impedance of the power supply unit with the impedance of the process chamber and the cable unit.

The effects of the present disclosure are not limited to the aforementioned effects, and other effects not mentioned herein will be clearly understood from the following description by those skilled in the art to which the present disclosure pertains.

Although the embodiments of the present disclosure have been described with reference to the accompanying drawings, it will be understood by those skilled in the art to which the present disclosure pertains that the present disclosure can be carried out in other detailed forms without changing the technical spirits and essential features thereof. Therefore, it should be understood that the embodiments described above are illustrative in all respects and not restrictive.

What is claimed is:

1. A substrate processing apparatus comprising:
a power supply unit;
a process chamber configured to receive power from the power supply unit;
a cable unit connected between the power supply unit and the process chamber; and
an impedance matching unit connected between the cable unit and the power supply unit and configured to match an impedance of the power supply unit with an impedance of the process chamber and the cable unit, and
wherein the cable unit includes:
a cable configured to connect the power supply unit to the process chamber;
an impedance measuring unit configured to measure an impedance of an entirety of the cable unit; and
an impedance adjusting unit configured to adjust the impedance of the entirety of the cable unit.

2. The substrate processing apparatus of claim 1, wherein the impedance adjusting unit includes a filter configured to block a specific frequency.

3. The substrate processing apparatus of claim 1, wherein the impedance adjusting unit includes a variable capacitor configured to adjust the impedance of the entirety of the cable unit.

4. The substrate processing apparatus of claim 3, wherein the variable capacitor includes a vacuum variable capacitor (VVC).

5. The substrate processing apparatus of claim 1, wherein the impedance matching unit includes a plurality of variable capacitors.

6. The substrate processing apparatus of claim 5, wherein at least one of the plurality of variable capacitors includes a vacuum variable capacitor (VVC).

7. The substrate processing apparatus of claim 1, wherein the impedance measuring unit includes a vector network analyzer (VNA).

8. The substrate processing apparatus of claim 1, wherein the power supply unit includes a plurality of AC power sources.

9. The substrate processing apparatus of claim 8, wherein a frequency range of one of the plurality of AC power sources is 58 MHz to 62 MHz.

10. The substrate processing apparatus of claim 8, wherein a frequency range of one of the plurality of AC power sources is 390 kHz to 410 kHz.

11. The substrate processing apparatus of claim 2, wherein the filter is configured to block AC current having a frequency range of 175 MHz to 185 MHz.

12. The substrate processing apparatus of claim 1, wherein the process chamber includes:
a chamber body providing a process space;
a shower head positioned within the chamber body; and
a stage positioned within the chamber body and positioned below the shower head, and
wherein the stage includes:
a chuck body;
a plasma electrode configured to generate plasma within the process chamber; and
a chuck electrode configured to fix a substrate.

13. The substrate processing apparatus of claim 12, wherein the stage further includes a ring-shaped edge electrode surrounding the plasma electrode to control the plasma in an edge region of the substrate.

14. The substrate processing apparatus of claim 1, wherein the cable unit further includes a data display unit configured to display the impedance of the entirety of the cable unit.

15. A substrate processing apparatus comprising:
a power supply unit including a plurality of AC power sources;
a process chamber receiving power from the power supply unit; and
a cable unit disposed between the power supply unit and the process chamber, and
wherein the cable unit includes:
a cable configured to connect the power supply unit to the process chamber;
an impedance measuring unit configured to measure an impedance of an entirety of the cable unit; and
an impedance adjusting unit configured to adjust the impedance of the entirety of the cable, and
wherein a frequency range of one of the plurality of AC power sources is 58 MHz to 62 MHz.

16. The substrate processing apparatus of claim 15, wherein the impedance adjusting unit includes:
a filter configured to block a current of a specific frequency; and
a variable capacitor.

17. The substrate processing apparatus of claim 15, wherein the impedance measuring unit includes a vector network analyzer (VNA).

18. A substrate processing method comprising:
loading a substrate into a substrate processing apparatus;
performing a process on the substrate in the substrate processing apparatus;
unloading the substrate from the substrate processing apparatus; and
adjusting an impedance of the substrate processing apparatus, and
wherein the substrate processing apparatus includes:
a process chamber;
a power supply unit providing power to the process chamber; and
a cable unit disposed between the power supply unit and the process chamber, and
wherein the cable unit includes:
a cable;
an impedance measuring unit configured to measure an impedance of an entirety of the cable unit; and
an impedance adjusting unit configured to adjust the impedance of the entirety of the cable unit, and
wherein the adjusting of the impedance of the substrate processing apparatus includes:
isolating the cable from the process chamber;
measuring the impedance of the entirety of the cable unit; and
adjusting the impedance of the entirety of the cable unit.

19. The substrate processing method of claim 18, wherein the cable unit further includes a data display unit configured to display the impedance of the entirety of the cable unit.

20. The substrate processing method of claim 18, wherein the impedance adjusting unit includes a filter configured to block AC power having a specific frequency.
